(19) United States
(12) Patent Application Publication
(10) Pub. No.: US 2018/0066991 A1
(43) Pub. Date: Mar. 8, 2018

(54) POLARIZATION-SELECTIVE SCATTERING ANTENNA ARRAYS BASED POLARIMETER

(71) Applicant: PRESIDENT AND FELLOWS OF HARVARD COLLEGE, Cambridge, MA (US)

(72) Inventors: Jan Philipp Balthasar MUELLER, Cambridge, MA (US); Kristjan LEOSSON, Cambridge, MA (US); Federico CAPASSO, Cambridge, MA (US)

(73) Assignee: PRESIDENT AND FELLOWS OF HARVARD COLLEGE, Cambridge, MA (US)

(21) Appl. No.: 15/556,995

(22) PCT Filed: Mar. 10, 2016
(86) PCT No.: PCT/US16/21678

§ 371 Date: Sep. 8, 2017

Related U.S. Application Data
(60) Provisional application No. 62/132,432, filed on Mar. 12, 2015.

(51) Int. Cl. G01J 4/02; G01N 21/47; H01Q 21/24; G01R 29/08; G01J 4/04

(52) U.S. Cl. CPC G01J 4/02; G01N 21/47; H01Q 21/24; G01J 2004/002; G01J 4/04; G01N 2021/4792; G01R 29/0892

(57) ABSTRACT

A polarimeter includes an integrated device with an array of antennas including multiple column pairs. Each column pair has two columns, and each column in each column pair includes multiple antennas. A first column of each column pair in the array scatters a first polarization component of an incident radiation, and a second column of each column pair in the array scatters a second polarization component of the incident radiation. The scattered fields of the column pairs interfere constructively in a direction depending on the polarization of the incident radiation, resulting in maximal intensity at a certain point in space for a specific polarization state. Multiple column pairs in parallel and oriented at angles with respect to each other can be used to scatter different polarization components of the incident radiation directionally to different points in space. Detectors are positioned with respect to the integrated device to detect polarization components.

### CROSS-REFERENCE TO RELATED PATENT APPLICATIONS

This application claims the benefit of U.S. Provisional Patent Application 62/132,432 filed Mar. 12, 2015 to Mueller et al., titled “Polarization-Selective Scattering Antenna Arrays Based Polarimeter,” the contents of which are incorporated herein by reference in their entirety.

### STATEMENT REGARDING FEDERALLY SPONSORED RESEARCH OR DEVELOPMENT

This invention was made with Government support under Grant No. FA9550-12-1-0289, awarded by the U.S. Air Force Office of Scientific Research; Grant No. FA9550-14-1-0389, awarded by the U.S. Air Force Office of Scientific Research; and Grant No. N66001-12-C-2011, awarded by the U.S. Office of the Director of National Intelligence Advanced Research Projects Activity. The Government has certain rights in the invention.

### FIELD OF THE DISCLOSURE

The present disclosure, in general, relates to polarization-selective scattering antenna arrays.

### BACKGROUND

Electromagnetic (EM) radiation has at least three fundamental properties: frequency, intensity and polarization. Measurements of the frequency and intensity of EM radiation are ubiquitous in modern technologies, such as photo and video cameras, light detectors and radar, wireless communications and optical networking. However, polarization measurements are not nearly as pervasive, even though the polarization of EM radiation may contain as much information as the shades of an image or the frequency of a radio signal, and the polarization properties of EM radiation can be used in many important applications. The underutilization of the polarization properties of EM radiations is at least partly related to the limited availability of suitable devices for measuring polarization, which generally suffer from high cost, large size and slow speed, or may even be unavailable for certain wavelength ranges.

### SUMMARY

A polarimeter includes an integrated device with an array of antennas including multiple column pairs. Each column pair has two columns, and each column in each column pair includes multiple antennas. A first column of each column pair in the array scatters a first polarization component of an incident radiation, and a second column of each column pair in the array scatters a second polarization component of the incident radiation. The scattered fields of the column pairs interfere constructively in a direction depending on the polarization of the incident radiation, resulting in maximal intensity at a certain point in space for a specific polarization state. Multiple column pairs in parallel and oriented at angles with respect to each other can be used to scatter different polarization components of the incident radiation directionally to different points in space. Detectors are positioned with respect to the integrated device to detect the combined scattered field of the columns of the column pairs. The polarization state of the incident radiation can be deduced from the directional scattering of the incident radiation by the antenna array.

The present disclosure provides, in some embodiments, a polarimeter including an integrated device with an array of antennas. The array includes multiple column pairs, each column pair in the array has two columns, and each column in each column pair includes multiple antennas. A first column of each column pair in the array scatters a first polarization component of an incident radiation, and a second column of each column pair in the array scatters a second polarization component. Detectors are positioned with respect to the integrated device to detect polarization components corresponding to superpositions of the first polarization component and the second polarization component.

The present disclosure provides, in some embodiments, an integrated polarization-selective scattering antenna array including multiple column pairs, each column pair includes two substantially parallel columns spaced apart from each other, each column includes multiple antennas. In a first column of each column pair, each antenna is oriented at an angle θ1 with respect to a column axis of the column pair. In a second column of each column pair, each antenna is oriented at an angle θ2 with respect to the column axis of the column pair, and θ1 is different from θ2.

The present disclosure provides, in some embodiments, a method for polarization measurement including coupling an incident radiation to an integrated polarization-selective scattering antenna array; measuring, using optical sensors disposed at predefined locations around the antenna array, intensities of different polarization components of the incident radiation scattered by the antenna array; and determining from the intensities a polarization state of the incident radiation and a degree of polarization of the incident radiation.

### BRIEF DESCRIPTION OF DRAWINGS

FIG. 1A illustrates a linearly polarized radiation.

FIG. 1B illustrates a linearly polarized radiation.

FIG. 1C illustrates an elliptically polarized radiation.

FIG. 1D illustrates a right-handed circularly polarized radiation.

FIG. 1E illustrates a left-handed circularly polarized radiation.

FIG. 2 illustrates a Poincaré Sphere.

FIG. 3A illustrates an example of a polarization-selective scattering antenna array.

FIG. 3B illustrates an example of a polarization-selective scattering antenna array.

FIG. 4A illustrates an example of a polarization-selective scattering antenna array.

FIG. 4B illustrates bidirectional coupling and scattering of a linearly polarized radiation by the antenna array structure of FIG. 4A.

FIG. 4C illustrates unidirectional coupling and scattering of a clockwise circularly polarized radiation by the antenna array structure of FIG. 4A.

FIG. 4D illustrates unidirectional coupling and scattering of a counterclockwise circularly polarized radiation by the antenna array structure of FIG. 4A.

FIG. 5A illustrates an example of a polarization-selective scattering antenna array.

FIG. 5B is an enlarged portion of FIG. 5A, illustrating one column pair.

FIG. 6A illustrates an example of a polarization-selective scattering antenna array.

FIG. 6B illustrates an example of polarization states represented on the Poincaré Sphere directionally scattered by the array of FIG. 6A.

FIG. 6C illustrates an example of a polarization-selective scattering antenna array.

FIG. 6D illustrates an example of polarization states represented on the Poincaré Sphere directionally scattered by the array of FIG. 6C.

FIG. 7 illustrates an example of a setup for measuring polarization state of an incident radiation using a polarization-selective scattering antenna array based polarimeter.

FIG. 8A illustrates an example of measured relative intensities and SOPs of an incident light with a wavelength of 1500 nm measured by the polarimeter of FIG. 5 and a reference polarimeter.

FIG. 8B illustrates an example of measured relative intensities and SOPs of an incident light with a wavelength of 1530 nm measured by the polarimeter of FIG. 5 and a reference polarimeter.

FIG. 8C illustrates an example of measured relative intensities and SOPs of an incident light with a wavelength of 1550 nm measured by the polarimeter of FIG. 5 and a reference polarimeter.

FIG. 8D illustrates an example of measured relative intensities and SOPs of an incident light with a wavelength of 1565 nm measured by the polarimeter of FIG. 5 and a reference polarimeter.

FIG. 9 illustrates radiation generated by a column of dipoles.

FIG. 10 illustrates calculation results.

FIG. 11 illustrates calculation results.

FIG. 12A illustrates an example of a free-space in-line polarimeter.

FIG. 12B illustrates an example of a fiber-based in-line polarimeter.

FIG. 12C illustrates an example of a metasurface based in-line polarimeter.

FIG. 13 illustrates an example of a polarization-selective scattering antenna arrays based polarimeter.

FIG. 14A illustrates an example of a polarization-selective scattering antenna arrays based polarimeter.

FIG. 14B illustrates an example of a polarization-selective scattering antenna arrays based polarimeter.

FIG. 14C illustrates an example of a polarization-selective scattering antenna arrays based polarimeter.

FIG. 15 illustrates an example of a polarization-selective scattering antenna arrays based polarimeter.

FIG. 16 illustrates an example of an array of many on-chip in-line polarimeters, for simultaneous monitoring of multiple signals in parallel.

Some or all of the figures are schematic representations by way of example; hence, they do not necessarily depict the actual relative size or locations of the components or devices shown. The figures are presented for the purpose of illustrating one or more embodiments with the explicit understanding that they will not be used to limit the scope or the meaning of the claims that follow below.

### DETAILED DESCRIPTION

The following examples and embodiments serve to illustrate the present disclosure. These examples are in no way intended to limit the scope of the disclosure.

The present disclosure describes polarization-selective scattering antenna arrays, polarimeters, and methods for polarimetry based on polarization-selective scattering of different polarization components of a radiation using polarization-selective scattering antenna arrays. Such arrays as described in some embodiments of the present disclosure may be subwavelength antenna arrays. A subwavelength antenna array may be formed using metasurfaces. As used in embodiments of the present disclosure, “wavelength” (or λ) refers to the wavelength of the incident radiation in the material in which the radiation is propagating, and “subwavelength” refers to a distance or length that is less than a wavelength of the radiation. The methods and devices disclosed herein have a number of advantages over other polarimeters, including cost-efficiency, high-speed measurements, light-saving geometry, small footprint, and adaptability to wavelength ranges where antennas are practical, for example, over about 400 nanometers.

The term polarimetry may refer to either the measurement of the polarization of an EM wave (light-measuring polarimetry) or to the way that an object changes the polarization of an EM wave (sample-measuring polarimetry). A sample-measuring polarimeter includes both a device that emits radiation with a known polarization towards a target and a light-measuring polarimeter that detects how the polarization was changed. Polarimeters described in embodiments of the present disclosure generally refer to light-measuring polarimeters unless explicitly stated otherwise.

In an electromagnetic (EM) radiation, polarization refers to the direction in which fields of an electromagnetic wave oscillate as the wave propagates through space. The SOP (state of polarization) refers to a motion of a field vector in one cycle of a periodic cycling.

An EM wave can be considered as including two independent wave motions. For example, the electric field of an EM wave propagating along a z-axis may oscillate along both the x-axis and the y-axis, so it can be convenient to represent the EM wave as a superposition of an x-polarized electric field wave and a y-polarized electric field wave. The electric field of an EM wave can then be described as in equation (1), where Eₓ and E_{y} respectively represent the x-and y-polarization components of the electric field, e^{iθ} represents a phase difference between Eₓ and E_{y},

$$( \begin{matrix}{E}_{x} \\ {E}_{y} {e}^{i θ}\end{matrix} )$$

represents the polarization state, and e^{iφ} represents phase of the EM wave.

$$\vec{E} = ( \begin{matrix}{E}_{x} \\ {E}_{y} {e}^{i θ}\end{matrix} ) {e}^{i φ} \qquad ( 1 )$$

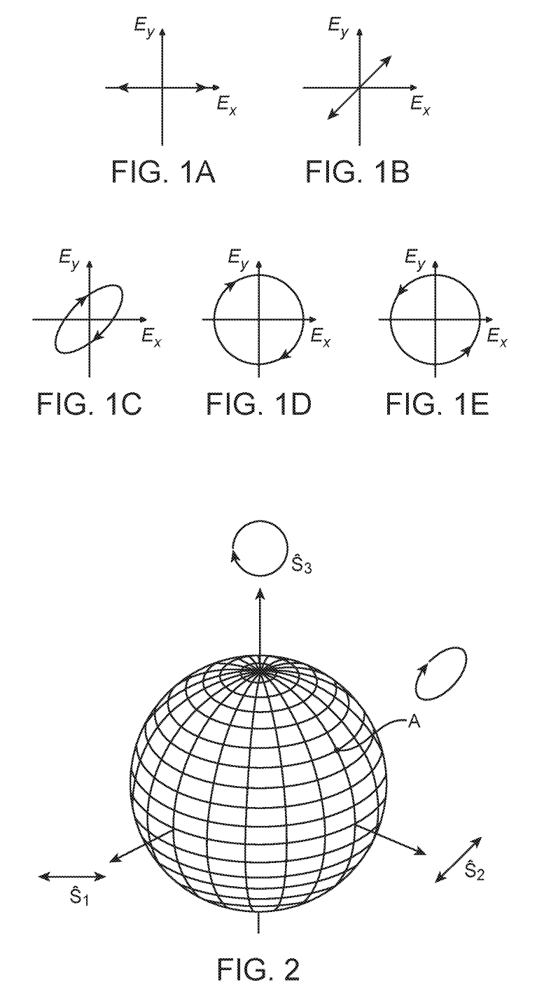

FIGS. 1A-1E illustrate that the superposition of the x-polarized wave and the y-polarized wave may result in a linear, circular or elliptical oscillation of the electric field in the x-y plane, depending on the relative phase and strengths of the x-polarized wave and the y-polarized wave. For example, if the phase difference θ between Eₓ and E_{y} is substantially zero, the light wave is linearly polarized as illustrated by FIGS. 1A and 1B. The amplitudes of Eₓ and E_{y} relative to each other determine the angle of the linear polarization. In FIG. 1A, the amplitude of the y-polarized wave (E_{y}) is substantially zero, so the polarization angle is substantially zero in the reference frame shown. In FIG. 1B, the amplitudes of Eₓ and E_{y} are substantially equal, and thus the angle of the linear polarization is about 45° in the reference frame shown.

If there is a phase difference between Eₓ and E_{y}, the light wave is elliptically polarized. In FIG. 1C, there is approximately a 45° phase difference between Eₓ and E_{y}, and thus an ellipse is shown having its long axis at approximately 45° in the reference frame shown. In FIGS. 1D and 1E, there is an approximately 90° phase difference between Eₓ and E_{y}, and thus the ellipse is shown as having an approximately circular shape. FIG. 1D illustrates a right-handed polarization and FIG. 1E illustrates a left-handed polarization.

EM waves may also be unpolarized, such as radiation emitted from a thermal light source. For an unpolarized wave, the EM field vector at a point in space does not undergo a predictable pattern. A radiation source is considered unpolarized, for example, when the polarization randomly changes on a timescale that is shorter than the time that a measurement can be conducted. A signal that contains both polarized and unpolarized components is referred to as partially polarized, and the fraction of the signal intensity corresponding to polarized radiation is referred to as the DOP (degree of polarization). Together, SOP and DOP characterize the polarization of an EM wave.

FIG. 2 illustrates a three-dimensional Cartesian space known as a Poincaré sphere centered at the origin of a 3-dimensional unit vector s with axes ŝ₁, ŝ₂ and ŝ₃. The state of polarization of an EM wave can be graphically represented as a point on the surface of the Poincaré Sphere, as shown by an example of a point ‘A’ in FIG. 2. Points on the principal axis ŝ₃ correspond to circularly polarized waves, and points on the equator axes ŝ₁, ŝ₂ correspond to linearly polarized waves, as shown in FIG. 2. In the example of point ‘A’ on the Poincaré Sphere in FIG. 2, the EM wave has a right-handed elliptical polarization state.

The polarization of an EM wave can be described mathematically using Jones vectors as in Equation (1), or using Stokes vectors with Stokes parameters S₀, S₁, S₂, and S₃. An EM wave can be described in terms of its total intensity (I), DOP (p), and shape parameters of the polarization ellipse. The relationship between the Stokes parameters, intensity and the polarization ellipse shape parameters can be described by equations (2), (3), (4) and (5), where I is the intensity of the wave; p∈(0 ,1) is the DOP; and ψ and χ represent ellipse shape parameters.

S₀=I (2)

S₁=Ip cos 2ψ cos 2χ (3)

S₂=Ip sin 2ψ cos 2χ (4)

S₃Ip sin 2ψ (5)

Equations (2)-(5) can also be represented as a 4-dimensional Stokes vector S as shown in equation (6).

$$S = ( \begin{matrix}{S}_{0} \\ {S}_{1} \\ {S}_{2} \\ {S}_{3}\end{matrix} ) = ( \begin{matrix}I \\ {Ips}_{1} \\ {Ips}_{2} \\ {Ips}_{3}\end{matrix} ) \qquad ( 6 )$$

The terms s₁, s₂ and s₃ in equation (6) are component values for the 3-dimensional vector s with axes ŝ₁, ŝ₂ and ŝ₃ represented as unit vectors: s=s₁ŝ₁+s₂ŝ₂+s₃ŝ₃. The angle ψof equations (2) and (3) is an angle in the ŝ₁-ŝ₂ plane, providing azimuth, and the angle χ in equations (2), (3) and (4) is an angle with the ŝ₃ axis, providing ellipticity of the SOP.

Polarimeters can be categorized in different ways. A polarimeter is a complete polarimeter if it can measure the full SOP and DOP information of an EM wave. Otherwise, it is referred to as an incomplete polarimeter. An example of an incomplete polarimeter is a microgrid polarimeter, which includes a set of linear polarizers in front of detectors. Such polarimeters may yield information of the azimuth of the SOP, but not the ellipticity of the SOP or the DOP.

Polarimeters may be punctual or imaging. A punctual polarimeter measures the polarization of the incident wave at a single point in space, while an imaging polarimeter can form an image by measuring the polarization of the incident wave at several closely-spaced points in space. If the polarization of the incident wave varies over the detection area of the polarimeter, the signal will appear to have a corresponding unpolarized component.

A polarimeter may be operational at different wavelength ranges. Some polarimeters use components that are only, or primarily, available in certain regions of the electromagnetic spectrum. For example, some polarimeters rely on polarization-modifying properties of components and materials, such as waveplates, liquid crystals, Pockels cells and special optical fibers. Complete polarimeters typically fall into this category, which is referred to as material-reliant polarimeters. The incorporation of carefully manufactured components made of special materials, such as waveplate retarders made of birefringent crystals, can add substantially to the cost of a polarimeter. The strength of the polarization-modifying properties of the special materials further imposes a size limitation on such components, which may hamper integration. For example, a Pockels cell may have a minimum length depending on the strength of the birefringence that can be induced in the cell. More often, suitable materials may not be available across a wide range of the spectrum. An example of a polarimeter that is not material-reliant is the aforementioned microgrid polarimeter, as linear polarizers can be implemented for most technologically relevant wavelengths.

Polarimeters can also be categorized as wavefront-dividing, intensity-dividing or time-dividing polarimeters. A wavefront-dividing polarimeter, such as the microgrid polarimeter, samples the incident wave at several points to determine the polarization state, assuming that the polarization is homogenous across the sampling area. An intensity-dividing polarimeter samples different polarization components of the incident light in parallel by splitting the intensity of the wave with beam splitters. An example of intensity-dividing polarimeters is an optical fiber polarimeter. Time-dividing polarimeters measure polarization by sampling different polarization components at different times, which include, for example, polarimeters with variable retarders such as liquid crystal cells and rotating waveplates. Such polarimeters can achieve smaller form factors than wavefront-dividing and intensity-dividing polarimeters, and may relatively improve signal-to-noise ratio as the signal is not divided. However, their time resolution may be limited by measurement speed. Polarimeters involving mechanical motion may also suffer from errors caused by imperfect alignment and may further suffer from gradual wear.

Polarimeters may be light-saving. While many polarimeters absorb most of the signal while performing a measurement, a light-saving polarimeter uses a fraction of the signal to determine polarization state. This has the advantage that the signal is still available for further processing, but may reduce the sensitivity of the polarimeter because a portion of the signal power is used for polarization measurement.

Table 1 summarizes characteristics of various polarimeter types and architectures, including polarimeters based on rotating waveplates, nematic liquid crystal, fixed waveplates and polarizers, crystal, optical fiber and metasurface pixels. Also shown in Table 1 are characteristics of a polarization-selective scattering antenna array based on a metasurface according to an embodiment of the present disclosure. In the “Feature” section of Table 1, a box absent shading indicates that the corresponding polarimeter is desirable for the feature, a lightly shaded box indicates that the corresponding polarimeter is satisfactory for the feature, and a darkly shaded box indicates that the corresponding polarimeter may not be satisfactory for the feature in some applications. As used in Table 1, “versatile” indicates that the corresponding architecture can be adapted to broad ranges of wavelengths.

As can be seen from Table 1, a metasurface polarimeter according to an embodiment of the present disclosure is desirable for the features ‘compact’, ‘fast’, ‘low cost’, ‘versatile’, and ‘light-saving’, while also being satisfactory for the feature ‘sensitive’. Thus, the metasurface polarimeter represents an improvement over other polarimeter types and architectures.

Some uses for a polarization-selective scattering antenna array polarimeter (e.g., based on metasurfaces) according to the present disclosure are provided next. These uses are provided by way of example and are not limiting. A polarization-selective scattering antenna array polarimeter according to the present disclosure provides a solution for detecting polarization in a compact, fast, low cost, versatile, light-saving and sensitive manner for these uses.

The ability to generate radiation with a deterministic polarization state is frequently desired in research, sensing and testing. To generate an arbitrary polarization state with precision, a polarimeter may be used for reference measurements.

Time-efficient polarization generation is important for optical information technology, where optical systems are tested for their polarization-dependent properties, and high accuracy of the testing is desirable.

By adding polarization information to spectral and intensity information, details otherwise hidden in images can be revealed, including information about surface orientation, roughness and material properties. This can be, among other things, used to defeat clutter in images and help distinguish otherwise camouflaged man-made structures from natural terrain. Further, a close relationship between scattering and polarization also renders polarization measurement a useful tool in remote sensing, such as environmental and atmospheric sensing, or to image through dust or clouds.

The interaction of materials with polarized light is a basis for analytic technologies in material analysis, including strain imaging, characterization of material chirality and precision metrology. The polarization dependent optical properties of biological tissues make polarization sensing a powerful technique with broad applications in biology and medicine, including detecting cervical, colon and skin cancer using polarized light, physiological monitoring of microorganisms, functional imaging of biological tissues, and early detection of glaucoma in human eyes. The chiral properties of many organic molecules provide optical measurement of concentrations in liquids, which may, for example, provide diabetics with a noninvasive way to monitor blood sugar.

Moreover, effects such as polarization mode dispersion, polarization-dependent loss, and polarization-dependent functionality of active and passive optical devices demand careful monitoring of polarization in optical networks.

As noted, the uses described above are some examples of how a polarization-selective scattering antenna array polarimeter according to the present disclosure can provide a solution for detecting polarization in a compact, fast, low cost, versatile, light-saving and sensitive manner, and other uses are also contemplated.

To measure the polarization of an EM wave, a polarimeter generally translates the polarization information of the wave to a set of intensities to be measured using power detectors. For example, the intensity of an EM wave passing through each of a series of polarization analyzers with known polarization states can be measured to determine the polarization state of the EM wave, which can be mathematically expressed as Pᵢ=mᵢS , where Pᵢ is the intensity detected after the EM wave passes through the ith polarization analyzer, which measures the polarization component mᵢ=(m_{i,0}, m_{i,1}, m_{i,2}, m_{i,3}) of the incident polarization S. The action of a polarimeter using a set of n polarization analyzers can thus be described by an n×4 matrix M as in equation (7).

$$P = ( \begin{matrix}{P}_{1} \\ {P}_{2} \\ ⋮ \\ {P}_{n}\end{matrix} ) = MS = ( \begin{matrix}{m}_{1 , 0} & {m}_{1 , 1} & {m}_{1 , 2} & {m}_{1 , 3} \\ {m}_{2 , 0} & {m}_{2 , 1} & {m}_{2 , 2} & {m}_{2 , 3} \\ ⋮ & ⋮ & ⋮ & ⋮ \\ {m}_{n , 0} & {m}_{n , 1} & {m}_{n , 2} & {m}_{n , 3}\end{matrix} ) ( \begin{matrix}{S}_{0} \\ {S}_{1} \\ {S}_{2} \\ {S}_{3}\end{matrix} ) \qquad ( 7 )$$

A polarimeter may include four or more polarization analyzers to determine the four components of the Stokes vector. When four polarization analyzers are used, the measurement of S can be achieved by inverting M such that S=M⁻¹P. When more than four polarization analyzers are used, the problem is over-determined and the solution may not be unique. In such cases, a solution can be found by minimizing the mean-square error using a pseudo-inverse matrix such that S=(M^{T}M)⁻¹M^{T}P. Thus, a polarimeter with more than four independent polarization analyzers can produce more accurate measurements by collecting more information. A polarimeter may include less than four polarization analyzers; however, the polarimeter may not measure the full SOP and DOP information of an EM wave if it includes less than four independent polarization analyzers.

In one or more embodiments of the present disclosure, the polarization analyzers used to construct polarimeters include arrays of subwavelength spaced antennas, such as linear arrays, which provide the polarization-selective scattering of select polarization states.

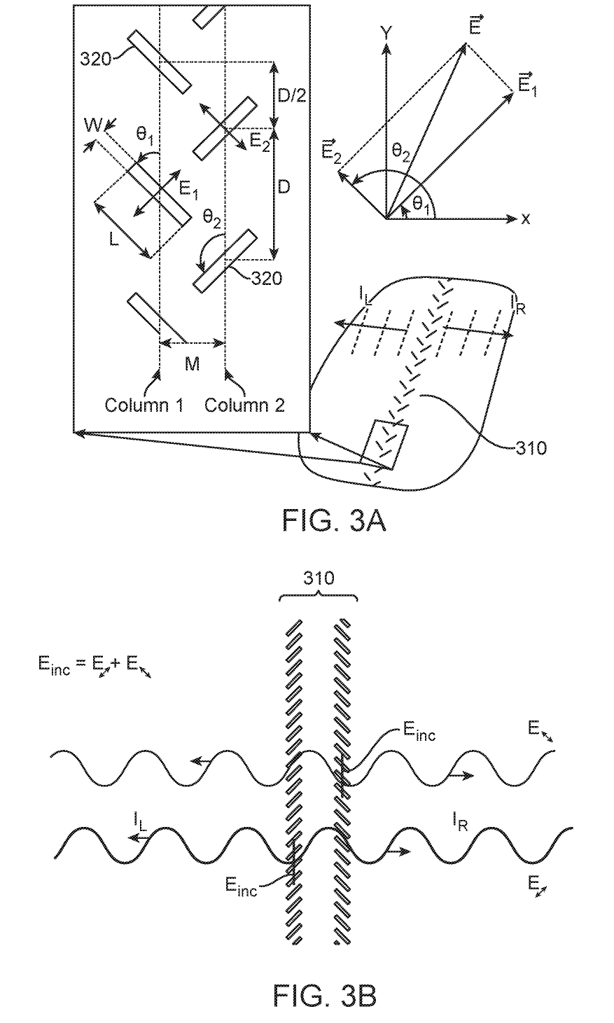

FIG. 3A illustrates an example of a polarization analyzer with an array 310 of two columns of subwavelength spaced rod antennas 320. The two columns of the array of FIG. 3 are substantially parallel and separated by a distance M, and the array is longer than it is wide, and has a longitudinal axis parallel to the columns. The antennas 320 in a column are oriented in a same direction with respect to the longitudinal axis of the array 310. For example, the antennas 320 of column 1 (as labeled in the enlarged inset in FIG. 3A) are oriented at an angle of about θ₁ with respect to the longitudinal axis, and the antennas 320 of column 2 (as labeled in the enlarged inset in FIG. 3A) are oriented at an angle of about θ₂=θ₁+90. Other orientations are also possible.

A center-to-center distance between two antennas 320 in a column is a distance D. In some embodiments, the antennas 320 in a column are spaced apart substantially equally, such that a center-to-center distance between each two adjacent antennas 320 in the column is substantially equal. The distance D is subwavelength, meaning that a distance between any two adjacent antennas 320 in a column is less than a wavelength of the incident EM wave. In some embodiments, antennas 320 of the two columns are staggered such that a center point of an antenna 320 in a first column (e.g., column 1) of the two columns, when projected onto a central axis of a second column (e.g., column 2) of the two columns, is approximately equidistant (a distance D/2) between the center points of two adjacent antennas 320 in the second column.

The antennas 320 selectively couple and scatter polarization components E₁ and E₂ of an incident wave E. Light scattered by the individual antennas 320 results in waves propagating away from the two columns at desired angles. Due to the subwavelength spacing of the antennas 320 in each column, the scattered fields may interfere with each other. In FIG. 3A, the scattering results in a wave propagating leftward with an intensity I_{L}, and another wave propagating rightward with an intensity I_{R}.

FIG. 3B illustrates that the two columns of the array 310 couple two independent polarization components of the incident wave (E_{inc}) and scatter them to the left and right of the column pair (with respective intensities I_{L} and I_{R}). The waves scattered by each column interfere with each other as a function of a spacing between the columns and a relative phase shift of the two polarization components. The incident radiation may be coupled by the two columns surface-normally or from other angles. At a point to each side of the column pair, an intensity of the scattered radiation is maximized for a particular incident polarization state. Thus, the column pair acts as a polarization analyzer. The polarization properties of the column pair can be controlled by the orientation and spacing of the antennas 320 of each column and the spacing M between the two columns in the column pair.

Although the polarization analyzer of FIGS. 3A and 3B is illustrated as columns of rod antennas, other configurations are also possible. A central property of the specific type of antenna used in the array is that the antenna scatters one linear polarization much more efficiently than the antenna scatters the other, orthogonal linear polarization state. Accordingly, the polarization analyzer of FIGS. 3A and 3B may be implemented with any type of antenna with this property.

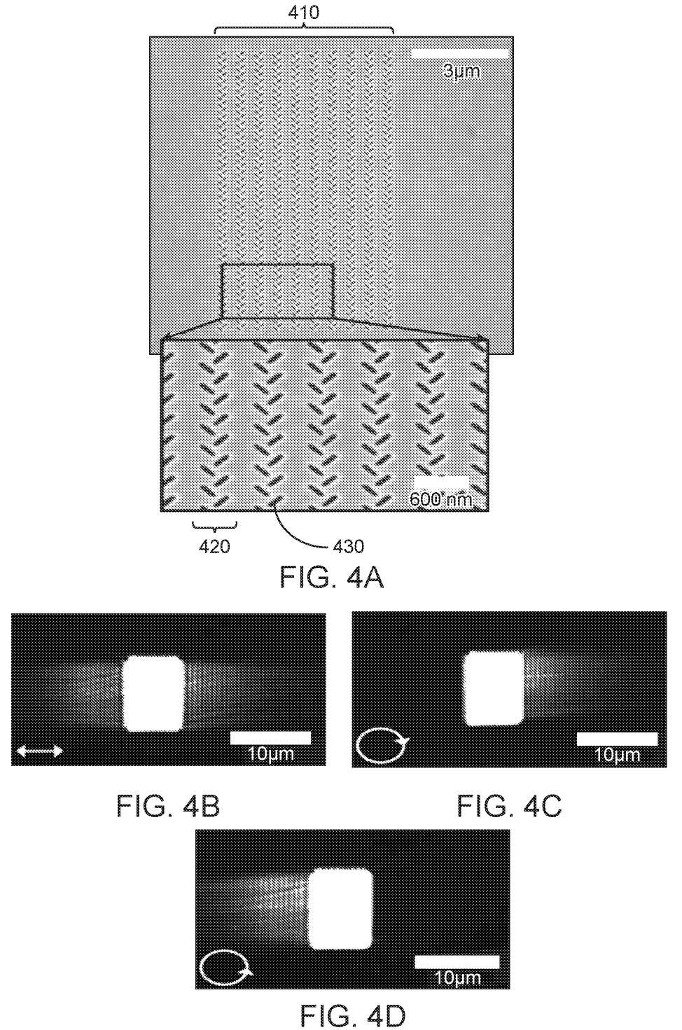

FIGS. 4A-4D illustrate a subwavelength antenna array structure 410 of ten column pairs 420 of metasurfaces used to unidirectionally and bidirectionally couple surface plasmon polaritons upon illumination by a polarized light. FIG. 4A illustrates the antenna array structure 410 including aperture antennas 430 on a gold film. As illustrated in FIG. 4B, under linear illumination, surface plasmon polaritons are launched equally towards both sides of the antenna array structure 410 (similarly to the scattering described with respect to FIG. 3B). FIGS. 4C and 4D illustrate unidirectional couplings of surface plasmon polaritons in opposite directions depending on the handedness of the circularly polarized incident radiation, where the antenna array structure 410 acts as a right-circular polarization analyzer when seen from the right, and a left-circular polarization analyzer when seen from the left.

In one or more embodiments, to function as a polarization analyzer for a polarimeter, the antenna array structure 410 illustrated in FIG. 4A can be modified in two ways. In a first way of modification, a distance between column pairs can be changed (e.g., from about (N+¼)λ to about (N+⅛)λ, where N is an integer), to perform polarization-selective coupling of elliptical polarization states. This allows the construction of an invertible device matrix with fewer polarization analyzers. In a second way of modification, orientations of the columns with respect to each other can be used as a design parameter to obtain polarization analyzers that can couple radiations of different polarization states.

In one or more embodiments, multiple sets of column pairs (e.g., 420) can be superimposed, stacked, or disposed side-by-side to form a complex structure in the form of a grating with several polarization analyzers. Measurements of the polarization analyzers can be made by detecting scattered radiation at several points next to the grating. For example, in some embodiments, an antenna array includes a number L of sets of antennas, each set including multiple column pairs, and the antenna array couples and scatter a number M of different polarization components of an incident radiation, where M is greater than or equal to two times L. For another example, in some embodiments, an antenna array includes a number Q of individual antenna areas (superimposed, stacked, or disposed side-by-side), the Q antenna arrays together are configured to couple and scatter a number R of different polarization components of an incident radiation, and R is greater than or equal to two times Q.

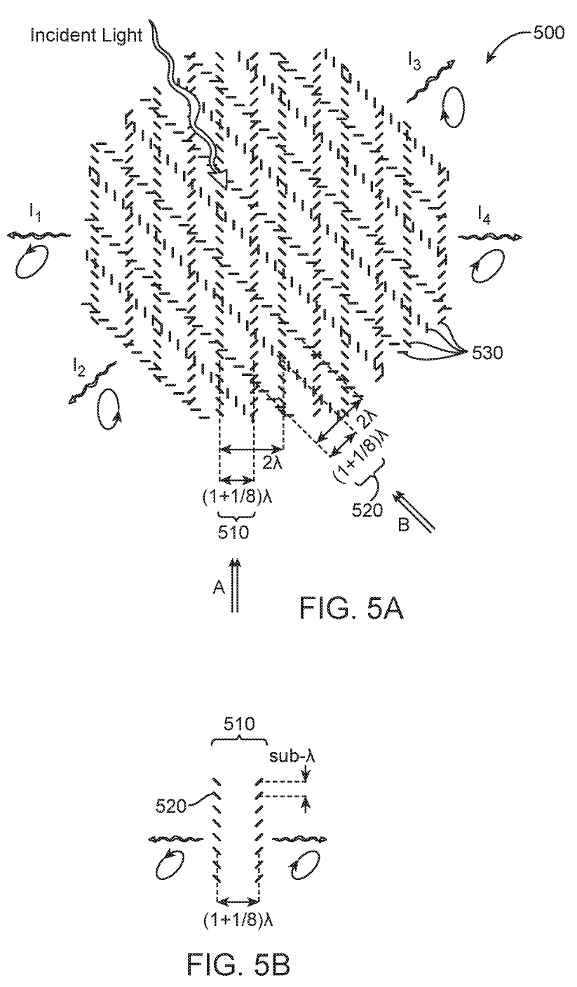

FIG. 5A illustrates an embodiment of a metasurface based structure 500 which may be used to form a polarimeter. The structure 500 incorporates two superimposed sets of column pairs, the two sets oriented at an angle with respect to each other. One set includes column pairs 510 oriented along a direction ‘A’, and the other set includes column pairs 520 oriented along a direction ‘B’. Each column pair 510 or 520 includes two columns of antennas 530. FIG. 5B is an enlarged portion of a column pair 510.

Each set (the set including column pairs 510 or the set including column pairs 520) functions as two polarization analyzers to sample two different polarization components of the incident radiation. The incident radiation may be coupled to the polarimeter surface-normally or from other angles. The scattered polarization components may be linearly, circularly or elliptically polarized.

In the embodiment illustrated in FIGS. 5A and 5B, the columns of a column pair 510 or a column pair 520 are shown as being separated by a distance of (1+⅛)λ, where λ is the wavelength of the incident radiation. More generally, the distance between two columns in a column pair (510 or 520) is about (N+n)λ, where N is an integer of 0 or greater, and n is a fractional number less than 1 (e.g., (N+⅛)λ). In some embodiments, the distance between columns in the column pairs 510 is different than the distance between columns in the column pairs 520.

In the embodiment illustrated in FIGS. 5A and 5B, column pairs 510 or 520 are shown as being positioned with a 2λ repetition (e.g., the left column of a first column pair 510 is a distance 2λ from a left column of an adjacent second column pair 510). In some embodiments, the column pairs (510 or 520) in a set are repeated about every Lλ, where L is an integer of 1 or greater (e.g., 2λ). In some embodiments, the column pairs 510 repeat about every L₁λ, while the column pairs 520 repeat about every L₂λ, where L₁ and L₂ are different integers of 1 or greater. In other embodiments, L₁ and L₂ are a same integer (similar to the embodiment shown in FIG. 5A).

The polarization components of the incident radiation are scattered radially away from the polarimeter in known directions, where they may be detected as intensities I₁-I₄ to determine the SOP. A polarimeter based on the structure 500 illustrated in FIG. 5A is capable of fully characterizing the SOP by sampling elliptically polarized components of the incident radiation. In some embodiments, the polarimeter illustrated in FIG. 5A is also capable of measuring DOP.

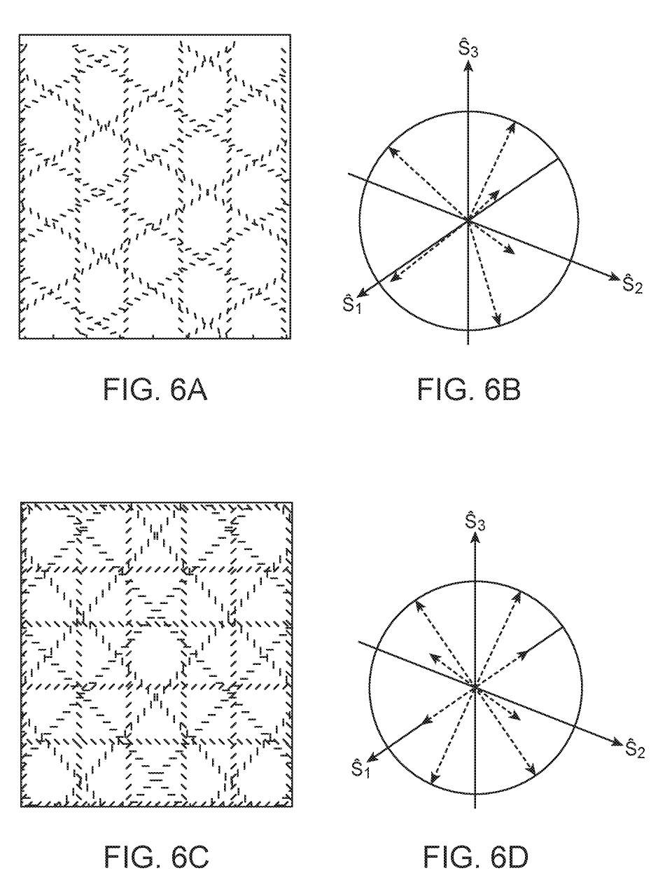

FIG. 6A illustrates a metasurface design with three sets of superimposed column pairs, each set functioning as two polarization analyzers to sample two different polarization components of the incident radiation. The metasurface design of FIG. 6A can be used to implement a polarimeter using six polarization analyzers. The metasurface design illustrated in FIG. 6A with three sets of superimposed column pairs yields a hexagonal lattice, which may help to alleviate issues related to alignment. The metasurface design illustrated in FIG. 6A is capable of measuring both SOP and DOP, thus can be used to construct a complete polarimeter. As described with respect to FIGS. 5A and 5B, distances between columns in a column pair may be the same in all sets, or may be different between sets. As also described with respect to FIGS. 5A and 5B, distances between column pairs may be the same for all sets, or may be different between sets.

FIG. 6B illustrates the six directionally scattered polarization components generated by the design of FIG. 6A.

FIG. 6C illustrates a metasurface design with four sets of superimposed column pairs, each set functioning as two polarization analyzers to sample two different polarization components of the incident radiation. The metasurface design of FIG. 6C can be used to implement a polarimeter using eight polarization analyzers, such as to minimize measurement error. The metasurface design of FIG. 6C is capable of measuring both SOP and DOP, thus can be used to construct complete polarimeters. As described with respect to FIGS. 5A and 5B, distances between columns in a column pair may be the same in all sets, or may be different between sets. As also described with respect to FIGS. 5A and 5B, distances between column pairs may be the same for all sets, or may be different between sets.

FIG. 6D illustrates the eight directionally scattered polarization components generated by the design of FIG. 6C.

Clutter caused by the amount of antennas may impose a fabrication dependent practical upper limit on the number of polarization analyzers, which may be solved by using stacked antenna arrays or by laterally displacing antenna arrays (e.g., wavefront division).

### Experimental Results—Two Sets of Columns

A polarization-selective scattering antenna array polarimeter using two sets of superimposed column pairs of metasurfaces, similar to the design illustrated FIG. 5, was fabricated and characterized. The antenna array structure was patterned on a silicon wafer using electron-beam lithography and electron-beam evaporation of gold, and was subsequently covered in a layer of spin-coated benzocyclobutene (BCB) polymer. Each individual antenna in the fabricated antenna array structure had a length of about 150 nanometers (nm), a width of about 50 nm, and a thickness of about 17 nm. Additionally, four out-coupling gratings were patterned at a distance of about 500 micrometers (μm) from the antenna array structure to couple the scattered polarization components out of the plane of the antenna array structure for measurement.

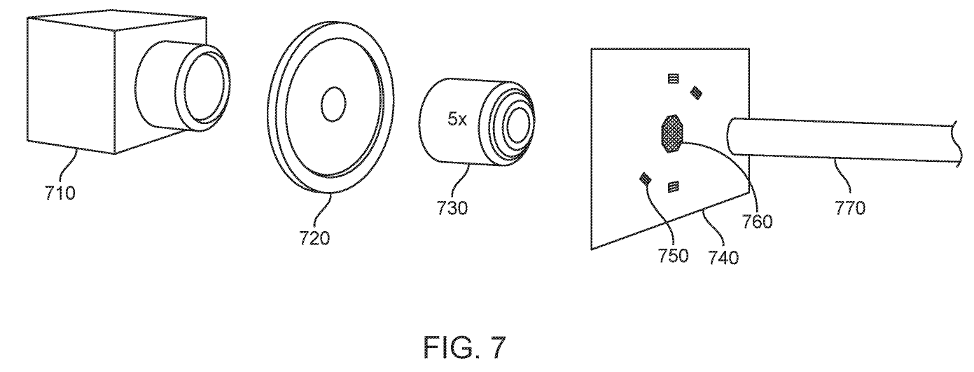

FIG. 7 illustrates a setup for measuring the polarization response of the fabricated metasurface based polarimeter. In the experiment, a single mode optical fiber 770 was placed in physical contact with a metasurface 760 based polarimeter 740. Light at a wavelength between 1500 nm and 1565 nm from a tunable laser source (not shown) was coupled into the fiber 770. This wavelength range covers the C-band in optical telecommunications (1530 nm-1565 nm), in particular, 1550 nm, which is considered a standard telecommunication wavelength. The metasurface 760 scattered incident light from the fiber 770 in four different directions towards four out-coupling gratings 750. A near infrared (NIR) camera 710, for example, an indium gallium arsenide (InGaAs) charge coupled device (CCD) array, was used to capture the intensities of the four different polarization components scattered from the four out-coupling gratings 750 after magnification (e.g., through a microscope objective 730). Light transmitted directly through the polarimeter 740 can optionally be blocked using an optical filter 720 to avoid saturating the camera 710. Camera 710 images indicated the four different polarization components scattered by the four out-coupling gratings 750 as bright dots, the intensities of which were proportional to the intensities of the four polarization components of the incident light scattered by the metasurface 760. It is to be noted that images from the camera 710 can be analyzed (e.g., using a script, such as MATLAB script) to extract the intensities of the four scattered polarization components.

By applying strain to the optical fiber 770, the polarization state of the light illuminating the polarimeter 740 can be adjusted. Adjusting the polarization state of the incident light results in changes in the intensities of the polarization components scattered by the out-coupling gratings 750. In one experiment, the polarization state of the incident light was adjusted to a number of different states, and the intensity of the scattered light was monitored for each polarization component.

In one experiment, the wavelength of the incident light was tuned to one of 1500 nm, 1530 nm, 1550 nm and 1565 nm. The polarization states were measured using the fabricated metasurface 760 based polarimeter 740 and also measured using a reference rotating-waveplate polarimeter designed for telecommunication wavelengths (Thorlabs PAX5710IR3-T).

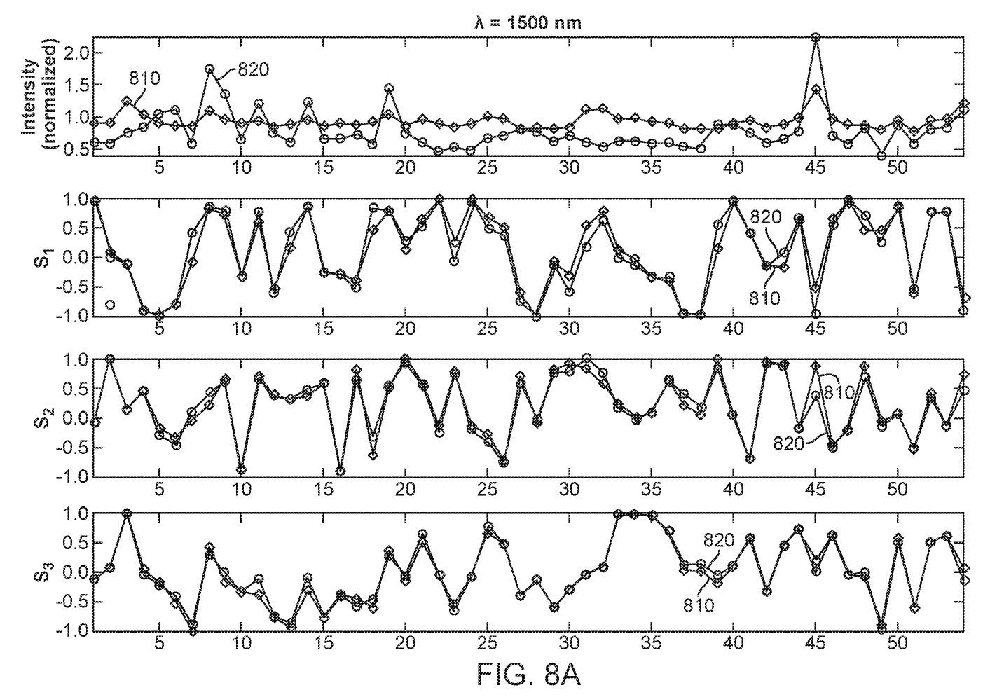

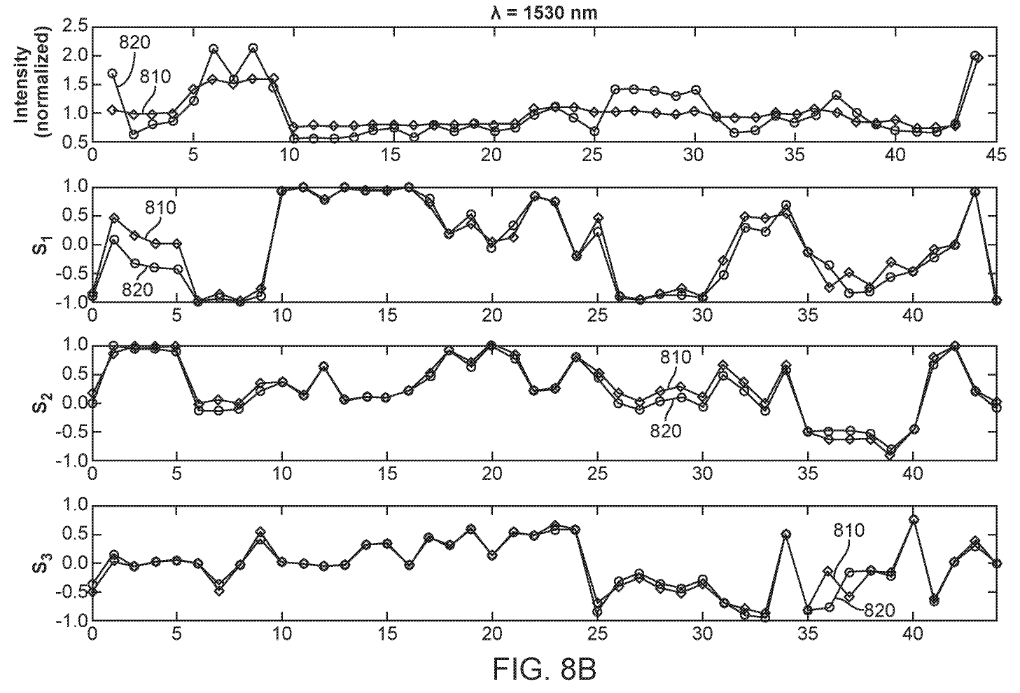

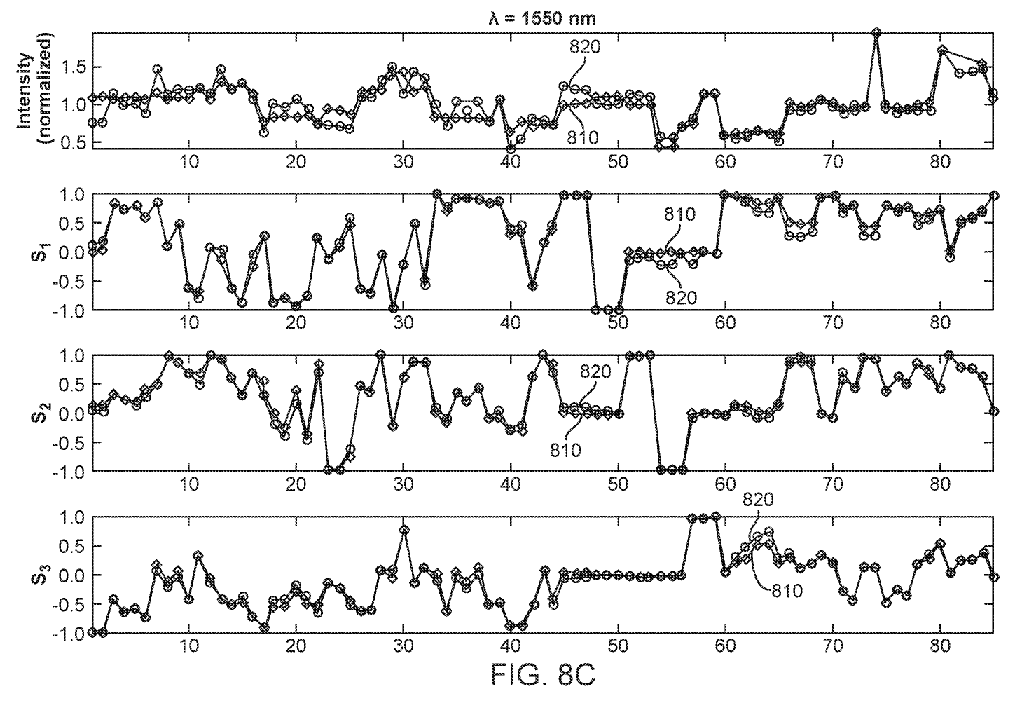

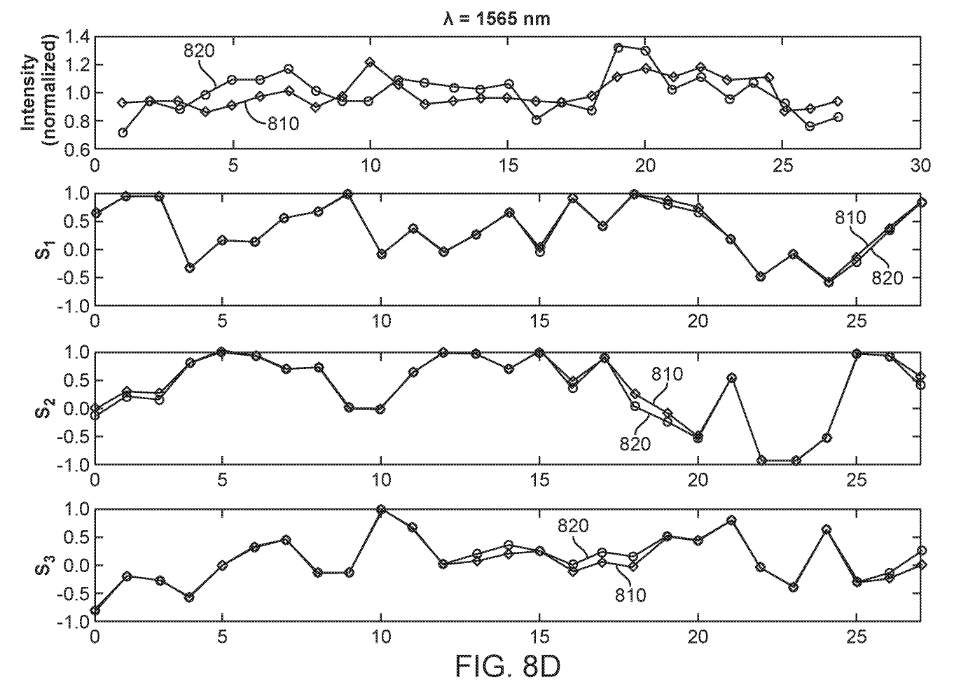

FIGS. 8A-8D illustrate the measurements results (lines labeled 820) of the fabricated metasurface 760 based polarimeter 740 for the same set of incident light compared with the measurement results (lines labeled 810) of the reference (Thorlabs) polarimeter for incident light with a wavelength of 1500 nm, 1530 nm, 1550 nm and 1565 nm, respectively. The polarization states of the set of incident light were selected so that they are representative of all possible polarization states. Even though the fabricated metasurface 760 characterized in the experiments was not designed for intensity measurements, it nevertheless was capable of measuring intensity with reasonable accuracy. The measurement results of the SOP in terms of Stokes vectors using the fabricated metasurface 760 based polarimeter 740 were in excellent agreement with those measured using the reference polarimeter. The observed performance of the polarimeter 740 may be subject to conditions of the specific experiment and may be further improved.

### Calibration

The metasurface based polarimeter can be calibrated by observing its polarization response to four different but known incident polarization states. Stokes vectors of the four different incident polarization states can be written as the rows of a matrix, which can be inverted to obtain the response of the polarimeter for each polarization component. The set of incident polarization states used for calibration can be selected to minimize the conditioning number with respect to matrix inversion of the aforementioned matrix. Once calibrated, the metasurface based polarimeter can be used to measure incident polarization states based on the intensities measured for the four different polarization components.

To determine the device matrix, a set of at least four sufficiently different, known polarization states are used to illuminate the polarimeter. A power P measured on an ith channel under illumination by a particular polarization S is given by the dot product of that channel's device vector Dᵢ and the incident Stokes vector P=S·Dᵢ (note Stokes vectors are real vectors, so S·Dᵢ=Dᵢ·S). Let a₁, a₂, a₃ . . . aₙ be the Stokes vectors of known polarization states used for the calibration of the polarimeter. Then the corresponding power measurements P on the ith channel are related to that channel's device vector Dᵢ via a matrix A that contains the Stokes vectors used for calibration as rows.

The device vector is then found by inverting the matrix A, that is: Dᵢ=A⁻¹P, where the left generalized inverse A⁻¹=(A^{T}A)⁻¹A^{T} can be used when n>4. The appropriate choice of the calibration polarizations a₁, a₂, a₃ . . . aₙ is such that the conditioning number of the corresponding matrix A is minimized. This minimizes the vulnerability of the measurement of Dᵢ to measurement error. Assuming that the noise of the power measurements is Gaussian, using more than four calibration polarizations to measure the device vectors reduces the least squares error.

### Simulation Results—Single Column

FIG. 9 illustrates that a single column 910 of dipoles may be used to generate cylindrical wave emissions. In FIG. 9, a simulation of an x-polarized field emitted by such a single column 910 is shown, where coupling between the dipoles is neglected. Shown is the x-polarized component of the electric field emitted by a long column 910 of dipoles parallel to the x-axis, located at y=0, z=0. The wavelength of the emitted wave shown in FIG. 9 is normalized to λ=1. The spacing of the individual antennas is 0.25λ.

To a good approximation, the electric far-field scattered by the column 910 of sub-wavelength spaced antennas is a cylindrical wave of the form shown in equation (8), where E₀ is the complex amplitude, r is the radial distance vector from the x-axis to the observation point, \hat{x} is a unit vector along the x-axis, and k is the wavevector of the cylindrical wave, with magnitude |k|=2π/λ.

$$E = \frac{{E}_{0} {e}^{ik \cdot r}}{\sqrt{\vert r \vert}} \hat{x} \qquad ( 8 )$$

The polarization of the scattered field is independent of the polarization of the wave that excites the antennas (it is along the axis of the column 910 of antennas). The field is predominantly polarized along the axis of the column 910. Following the cylindrical wave approximation, the intensity |Eₓ|² of the Eₓ component of the electric field decays as the inverse of the distance. Consequently, 1/|Eₓ|² increases linearly away from the column 910.

### Simulation Results—Multiple Pairs of Antenna Columns

To increase a cross-section of a polarimeter, several pairs of columns can be spaced in parallel at a distance that corresponds to an integer multiple of the wavelength. For 2N+1 pairs spaced apart by D, the scattered field is related to a function f_{N}, shown in equation (9).

$${f}_{N} ( \vert k \vert D cos θ ) = [ {\sum }_{n + - N}^{n = N} {e}^{- i n \vert k \vert D cos θ} ] \qquad ( 9 )$$

The function f_{N} depends on N (the number of column pairs) as well as a ratio of the spacing to the wavelength (D/λ), but not on polarization. Additional column pairs therefore do not affect the polarization response of the array, but they do affect the directionality of the scattered field.

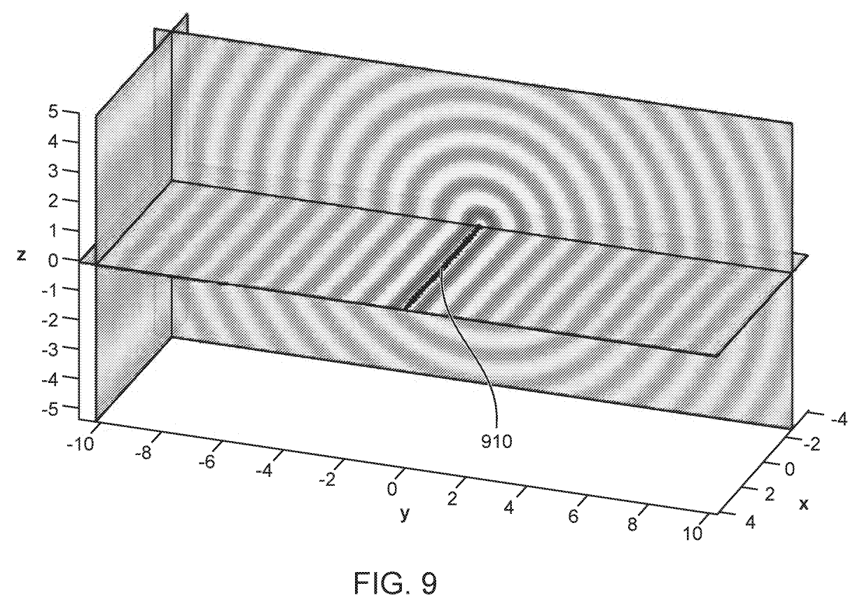

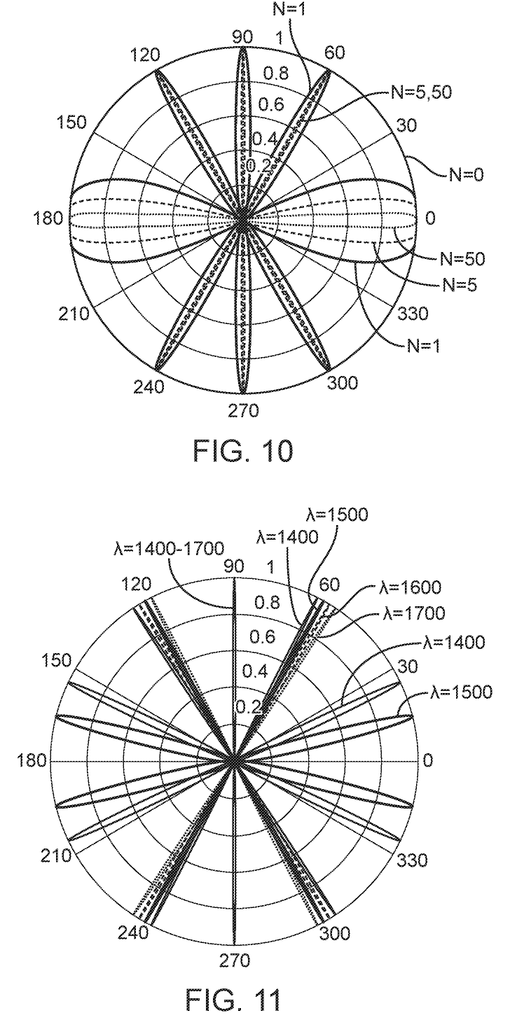

FIG. 10 illustrates simulation results of the function f_{N} for |k|D=2 and for N=0, 1, 5, 50 (corresponding to 1, 3, 11 and 51 column pairs). As expected, for a single column pair |f_{N}|² results in no modulation of the scattered field. For N>0, diffraction orders emerge, which become sharper but do not change angle with increasing N.

FIG. 11 illustrates normalized modulation |f_{N}|²/(2N+1)² of the radiated intensity due to the presence of multiple column pairs, where D=2000 nm and the free-space wavelength is varied from 1400 nm to 1700 nm. The first-order diffraction lobes at θ≈±60° and θ≈±120° are relatively insensitive to this wavelength variation.

Polarization-selective scattering antenna arrays have been described, and shown by way of example in several embodiments. The polarization-selective scattering antenna arrays may be used to construct polarimeters, as has also been described and illustrated. Polarimeters according to the present disclosure provide advantages over conventional polarimeters, and some examples follow.

A polarimeter according to embodiments of the present disclosure is transmissive, so it may be used at an interface of a waveguide structure (for example an optical fiber) and free space to measure the polarization of the output from, or input into, the waveguide. A polarimeter according to embodiments of the present disclosure may also be used to measure light that propagates in freespace (free-space to free-space) or that propagates in a waveguide (waveguide to waveguide). These capabilities represent an unusual flexibility in terms of the way in which the polarimeter may be deployed.

Further, conventional fiber-based in-line polarimeters are in practice limited to measurement of relative changes of polarization state. Polarimeters as described in embodiments of the present disclosure are, in contrast, capable of absolute determination of polarization state, because of the localized nature of the measurement.

Because antenna array designs according to embodiments of the present disclosure are conducive to on-chip integration, concurrent fabrication of many polarimeters using wafer-based nanofabrication techniques is possible. This also provides for efficient fabrication of arrays of polarimeters on a single chip that can measure multiple channels in parallel.

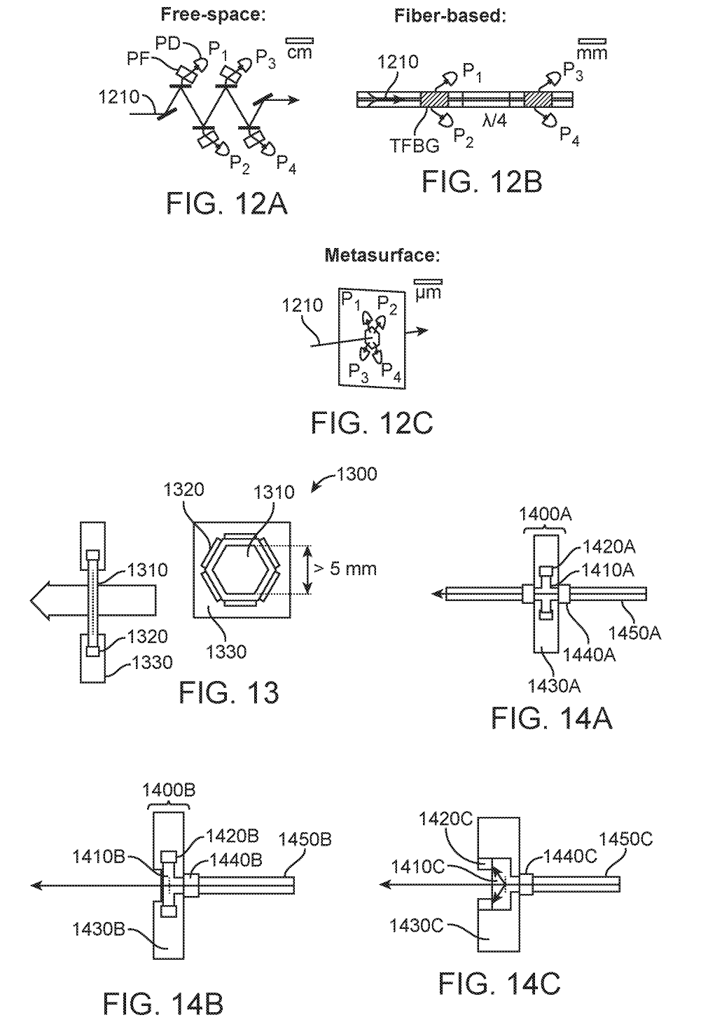

FIGS. 12A-12C provide a relative size comparison of a free-space in-line polarimeter using mirrors (FIG. 12A), a fiber-based in-line polarimeter (FIG. 12B), and a metasurface based in-line polarimeter according to an embodiment of the present disclosure (FIG. 12C). A free-space polarimeter (e.g., FIG. 12A) is generally implemented in a centimeter (cm) scale and a fiber-based polarimeter (e.g., FIG. 12B) is generally implemented in a millimeter (mm) scale, whereas a metasurface polarimeter according to an embodiment of the present disclosure (e.g., FIG. 12C) may be implemented in a micrometer (μm) scale. In FIGS. 12A-12C, PD refers to a photodetector, PF refers to a polarization filter, TFBG refers to a tilted fiber Bragg grating, λ/4 refers to a quarter waveplate, and P1-P4 refer to power measurements of the polarization components.

FIG. 13 illustrates an example of how a reduced-size free-space in-line polarimeter 1300 may be arranged using metasurfaces according to an embodiment of the present disclosure. On the left is a side view of the free-space in-line polarimeter 1300 illustrating the narrowness of the polarimeter 1300, and on the right is a front view of the free-space in-line polarimeter 1300 illustrating that photodetectors 1320 may be placed around a periphery of a polarimeter chip 1310 to form the polarimeter 1300. The polarimeter 1300 further includes a package 1330, which may be formed, for example, from a molding compound. In this embodiment, a dimension of the polarimeter chip 1310 is greater than 5 mm. In other embodiments, dimensions of the polarimeter chip 1310 may be less than 5 mm.

FIG. 14A illustrates a fiber in-line polarimeter 1400A using metasurfaces according to an embodiment of the present disclosure. The polarimeter 1400A includes a polarimeter chip 1410A, photodetectors 1420A, and a package 1430A. The polarimeter 1400A attaches to a fiber 1450A through fiber ports 1440A.

FIG. 14B illustrates a fiber-to-free-space polarimeter 1400B using metasurfaces according to an embodiment of the present disclosure. The polarimeter 1400B includes a polarimeter chip 1410B, photodetectors 1420B, and a package 1430B. The polarimeter 1400B attaches to a fiber 1450B through a fiber port 1440B.

FIG. 14C illustrates a fiber-to-free-space polarimeter using metasurfaces according to an embodiment of the present disclosure. The polarimeter in FIG. 14C includes a polarimeter chip 1410C, photodetectors 1420C, and a package 1430C. The polarimeter attaches to a fiber 1450C through a fiber port 1440C. In this embodiment, a widest dimension of the package 1430 (in a vertical direction in the orientation shown) is decreased by positioning the photodetectors adjacent to the polarimeter chip 1410C in a direction along the fiber 1450C.

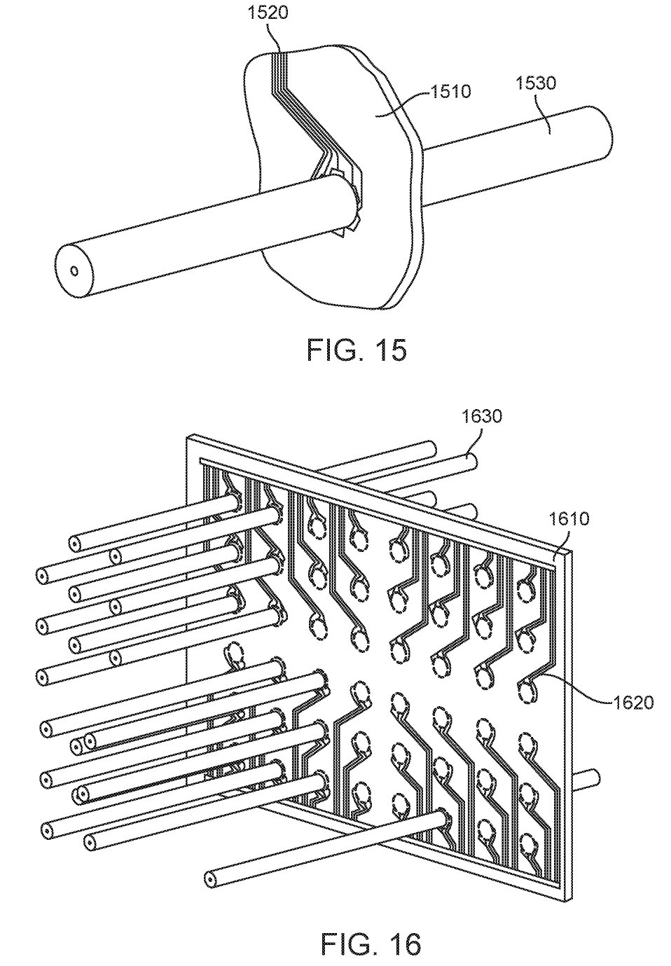

FIG. 15 illustrates an on-chip fiber in-line polarimeter 1510 in line with a fiber 1530, in which light detectors 1520 are integrated on-chip with the polarization-sorting scatterer.

FIG. 16 illustrates an array 1610 of many on-chip in-line polarimeters with integrated light detectors 1620 for a simultaneous monitoring of many signals on many fibers 1630 in parallel.

The present disclosure contemplates methods, systems and program products on a non-transitory machine-readable storage media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, “substantially perpendicular” can refer to an angle or orientation between two objects or surfaces that is within ±10° of 90°, such as within ±5°, ±4°, ±3°, ±2°, ±1°, ±0.5°, ±0.1°, or ±0.05°, and “substantially parallel” or “substantially in parallel” can refer to an angle or orientation between two objects or surfaces that is within ±10° of 0°, such as within ±5°, ±4°, ±3°, ±2°, ±1°, ±0.5°, ±0.1°, or ±0.05°. Distances between sets of objects can be deemed to be “substantially equal” if a standard deviation of the distances is less than or equal to ±10% of a mean of the distances, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

While the disclosure has been described with reference to the specific embodiments thereof, it should be understood by those skilled in the art that various changes may be made and equivalents may be substituted without departing from the true spirit and scope of the disclosure as defined by the appended claims. In addition, many modifications may be made to adapt a particular situation, material, composition of matter, method, operation or operations, to the objective, spirit and scope of the disclosure. All such modifications are intended to be within the scope of the claims appended hereto. In particular, while certain methods may have been described with reference to particular operations performed in a particular order, it will be understood that these operations may be combined, sub-divided, or re-ordered to form an equivalent method without departing from the teachings of the disclosure. Accordingly, unless specifically indicated herein, the order and grouping of the operations is not a limitation of the disclosure.

What is claimed is:

1. A polarimeter, comprising:
an integrated device comprising a first array of antennas:
the first array comprising a plurality of column pairs,
each column pair in the first array comprising two columns,
each column in each column pair comprising a plurality of antennas,
a first column of each column pair in the first array being configured to scatter a first polarization component of an incident radiation, and
a second column of each column pair in the first array being configured to scatter a second polarization component of the incident radiation; and
a plurality of detectors, each of the detectors positioned with respect to the integrated device to detect one of a plurality of polarization components corresponding to superpositions of the first polarization component and the second polarization component.

2. The polarimeter of claim 1, wherein a distance between two columns in each column pair is substantially equal.

3. The polarimeter of claim 2, wherein the distance is about (N+n)λ, N is an integer, n is a fractional number, and λ is a wavelength of the incident radiation.

4. The polarimeter of claim 1, wherein the column pairs of the first array are positioned at intervals of Lλ, where L is an integer and λ is a wavelength of the incident radiation.

5. The polarimeter of claim 1, wherein a first longitudinal axis of the first array is substantially parallel to a column axis of each of the column pairs of the first array, the integrated device further comprising a second array of antennas, wherein a second longitudinal axis of the second array forms an angle with the first longitudinal axis of the first array.

6. The polarimeter of claim 5, wherein the angle is about ninety degrees.

7. The polarimeter of claim 5, wherein the second array is integrated in the integrated device.

8. The polarimeter of claim 5, wherein the integrated device is a first integrated device, the polarimeter further comprises a second integrated device, and the second array is integrated in the second integrated device.

9. The polarimeter of claim 5, wherein
the second array comprises a plurality of column pairs,
each column pair in the second array comprises two columns,
each column in each column pair in the second array comprises a plurality of second array antennas,
a first column of each column pair in the second array is configured to scatter a third polarization component of the incident radiation in a third direction, and
a second column of each column pair in the second array is configured to scatter a fourth polarization component of the incident radiation in a fourth direction different from the third direction.

10. The polarimeter of claim 1, wherein the detectors are integrated in the integrated device.

11. An integrated polarization-selective scattering antenna array, comprising:
a plurality of column pairs, each column pair comprising two substantially parallel columns spaced apart from each other, each column comprising a plurality of antennas;
in a first column of each column pair, each antenna is oriented at an angle θ₁ with respect to a column axis of the column pair;
in a second column of each column pair, each antenna is oriented at an angle θ₂ with respect to the column axis of the column pair; and
θᵢ is different from θ₂.

12. The antenna array of claim 11, wherein the antennas in each column are spaced apart by a distance less than a wavelength of an incident radiation.

13. The antenna array of claim 11, wherein a space between the two columns in each column pair is n or (N+n) times a wavelength of an incident radiation, wherein N is an integer, and n is a fractional number.

14. The antenna array of claim 11, wherein a difference between θ₁ and θ₂ is 90°.

15. The antenna array of claim 11, wherein the antenna array is configured to couple and scatter two different polarization components of an incident radiation.

16. The antenna array of claim 11, wherein the column pairs are arranged in a number L of sets, and the antenna array is configured to couple and scatter a number M of different polarization components of an incident radiation, and M is greater than or equal to two times L.

17. The antenna array of claim 11, wherein the antenna array is a first antenna array, further comprising a number Q of antenna arrays including the first antenna array, the Q antenna arrays together configured to couple and scatter a number R of different polarization components of an incident radiation, and R is greater than or equal to two times Q.

18. The antenna array of claim 17, wherein the Q antenna arrays are stacked or disposed side-by-side.

19. The antenna array of claim 11, wherein the antenna array is a first antenna array of a plurality of antenna arrays in a multi-channel in-line polarimeter, and each of the plurality of antenna arrays is configured to receive incident light from a different one of multiple channels, for concurrent monitoring of the different channels.

20. A method for polarization measurement, comprising:
coupling an incident radiation to an integrated polarization-selective scattering antenna array;
measuring, using optical sensors disposed at predefined locations around the antenna array, intensities of different polarization components of the incident radiation scattered by the antenna array; and
determining from the intensities a polarization state of the incident radiation and a degree of polarization of the incident radiation.

21. The method of claim 20, wherein measuring the intensities of the polarization components of the incident radiation includes measuring intensities of four different polarization components.
